(19) United States
(12) Patent Application Publication
(10) Pub. No.: US 2016/0077913 A1
(43) Pub. Date: Mar. 17, 2016

(54) METHOD OF CONTROLLING NONVOLATILE MEMORY

(71) Applicant: Kabushiki Kaisha Toshiba, Minato-ku (JP)

(72) Inventors: Hiroshi YAO, Yokohama (JP); Hiroshi SUKEGAWA, Nerima (JP); Tokumasa HARA, Kawasaki (JP)

(73) Assignee: Kabushiki Kaisha Toshiba, Minato-ku (JP)

(21) Appl. No.: 14/636,512

(22) Filed: Mar. 3, 2015

Related U.S. Application Data
(60) Provisional application No. 62/048,833, filed on Sep. 11, 2014.

(51) Int. Cl. G06F 11/10; G11C 29/52; G11C 16/16

(52) U.S. Cl. CPC G06F 11/1068; G11C 16/16; G11C 29/52

(57) ABSTRACT

According to an embodiment, The control method includes reading a plurality of first pages in parallel on the basis of respectively different operation parameters. each of the first pages is respectively included in a plurality of first blocks. Each of the operation parameters includes a read voltage. The control method includes performing error correction on each of read data, and selecting one operation parameter out of the plurality of different operation parameters based on a result of the error correction.

### CROSS-REFERENCE TO RELATED APPLICATIONS

This application is based upon and claims the benefit of priority from U.S. Provisional Patent Application No. 62/048,833, filed on Sep. 11, 2014; the entire contents of which are incorporated herein by reference.

### FIELD

The present embodiment generally relates to a method of controlling nonvolatile memory.

### BACKGROUND

The flash memory records data by programming a threshold voltage depending upon a value to be recorded in each memory cell. However, the threshold voltage of the flash memory is changed according to various factors. As a result, an error is caused in read data sometimes.

In order to cope with the error, data to be recorded is protected by using an error correcting code and the error is removed by executing decoding at the time of reading. If the quantity of errors exceeds the capability of the error correcting code, the errors cannot be removed.

Therefore, there is a method of changing operation parameters little by little when reading data, repeating data reading and error correction, and searching a suitable read voltage with which errors are held down to within the correction capability. Reading a read target page is repeated a plurality of times in this method, however, it takes a longer time for read processing.

### BRIEF DESCRIPTION OF THE DRAWINGS

FIG. 1 is a functional block diagram illustrating an internal configuration of a memory system;

FIG. 2 is a diagram illustrating an example of an internal circuit configuration of a block;

FIG. 3 is a diagram illustrating an example of a change and distribution of a threshold voltage;

FIG. 4 is a diagram illustrating read processing using a plurality of read voltages;

FIG. 5 is a diagram conceptually illustrating search for a read voltage according to a first embodiment;

FIG. 6 is a flow chart illustrating read processing in the first embodiment;

FIG. 7 is a flow chart illustrating selection processing of an optimum read voltage in the first embodiment;

FIG. 8 is a diagram conceptually illustrating logical blocks;

FIG. 9 is a flow chart illustrating test block selection processing in a second embodiment;

FIG. 10 is a diagram conceptually illustrating intra-page ECCs and inter-page ECCs;

FIG. 11 is a diagram conceptually illustrating re-read processing in a third embodiment; and

FIG. 12 is a flow chart illustrating read processing in the third embodiment.

### DETAILED DESCRIPTION

According to the present embodiment, a nonvolatile memory includes a plurality of blocks. each of the blocks is a unit of data erasing. each of the blocks includes a plurality of pages. each of the pages is a unit of data writing and reading. A method of controlling the nonvolatile memory comprises reading a plurality of first pages in parallel based on respectively different operation parameters. each of the first pages is respectively included in a plurality of first blocks. Each of the operation parameters include a read voltage. The method comprises performing error correction on each of read data, and selecting one operation parameter out of the plurality of different operation parameters based on a result of the error correction.

A method of controlling nonvolatile memory according to embodiments will be descried below with reference to the accompanying drawings. By the way, the present invention is not limited to the embodiments.

### First Embodiment

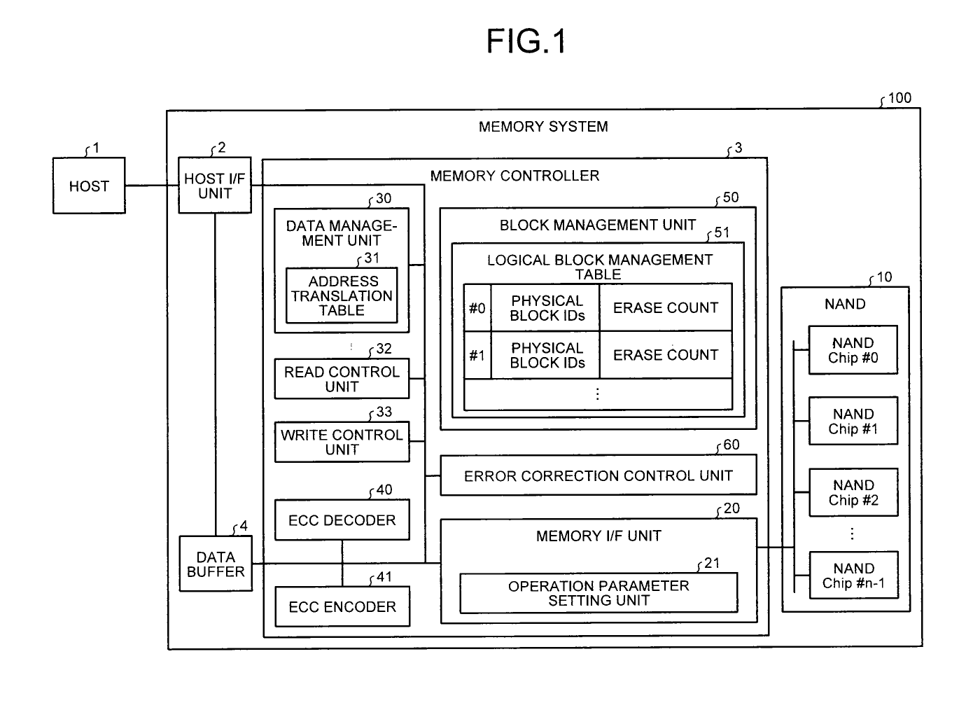

FIG. 1 illustrates a configuration example of a memory system 100. The memory system 100 is connected to a host device 1 (hereafter abbreviated to host) and functions as an external storage device of the host 1 via a host interface unit 2. The host 1 is, for example, a personal computer, a mobile phone, or an imaging device.

The memory system 100 includes a host I/F unit 2, a NAND type flash memory (hereafter abbreviated to NAND) 10 functioning as nonvolatile memory, a memory controller 3, and a data buffer 4. The memory controller 3 includes a memory interface unit 20, a data management unit 30, a read control unit 32, a write control unit 33, an ECC decoder 40, an ECC encoder 41, a block management unit 50, and an error correction control unit 60. By the way, the nonvolatile memory may be a memory other than the NAND flash memory. The nonvolatile memory may be a memory such as, for example, a NAND flash memory of three-dimensional lamination type, RERAM (resistance random access memory), or FERAM (Ferroelectric Random Access Memory).

The NAND 10 stores user data transferred from the host 1, management information of the memory system 100, system data and the like. The NAND 10 includes a memory cell array in which a plurality of memory cells are arranged in a matrix form. Each memory cell is capable of binary or multi-value storing. The NAND 10 includes a plurality of memory chips #0 to #n−1.

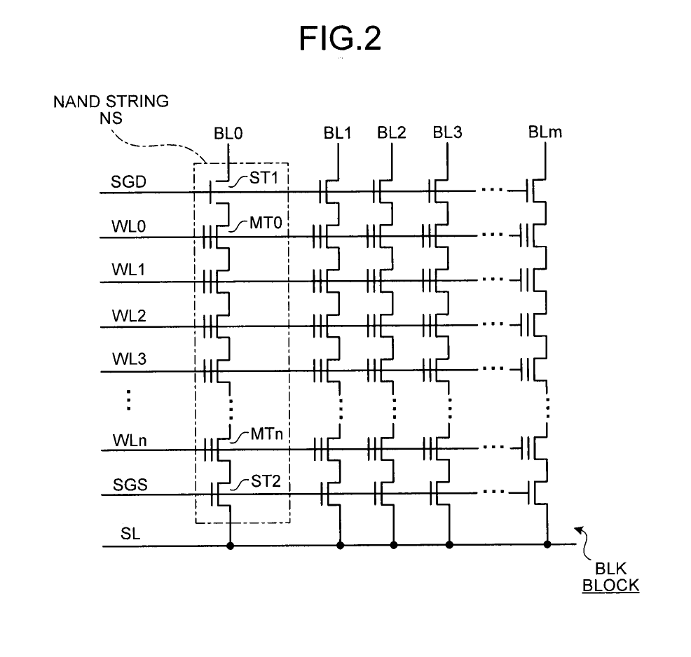

In the NAND 10, in general, block is a minimum unit of data erasing, and page is a unit of writing and reading. FIG. 2 is a diagram illustrating a circuit configuration example of a block in the NAND 10. As illustrated in FIG. 2, a block BLK in the NAND 10 includes (m+1) (where m is an integer of at least 0) NAND strings NS. Each NAND string NS includes (n+1) (where n is an integer of at least 0) memory cell transistors MT0 to MTn connected in series with adjacent memory cell transistors MT sharing a diffusion region (a source region or a drain region), and selection transistors ST1 and ST2 disposed respectively at both ends of a column of the (n+1) memory cell transistors MT0 to MTn.

Word lines WL0 to WLn are connected to control gate electrodes of the memory cell transistors MT0 to MTn included in the NAND string NS, respectively. The memory cell transistors MTi (i=0 to n) in the NAND strings NS are connected in common by the same word line WLi (i=0 to n). In other words, control gate electrodes of the memory cell transistors MTi in the same row in the block BLK are connected to the same word line WLi.

Each of the memory cell transistors MT0 to MTn is formed of a field effect transistor having a laminate gate structure formed on a semiconductor substrate. Here, the laminate gate structure includes a charge storage layer (floating gate electrode) formed over the semiconductor substrate with a gate insulation film between and a control gate electrode formed over the charge storage layer with an inter-gate insulation film between. Each of the memory cell transistors MT0 to MTn changes in threshold voltage depending on the number of electrons stored in the floating gate electrode. Each of the memory cell transistors MT0 to MTn can store data depending on a difference of the threshold voltage.

Bit lines BL0 to BLm are connected to drains of (m+1) selection transistors ST1 in one block BLK, respectively. A selection gate line SGD is connected to gates of the (m+1) selection transistors ST1 in common. Furthermore, a source of the selection transistor ST1 is connected to a drain of the memory cell transistor MT0. In the same way, a source line SL is connected to sources of the (m+1) selection transistors ST2 in one block BLK in common. A selection gate line SGS is connected to gates of the (m+1) selection transistors ST2 in one block BLK in common. Furthermore, a drain of the selection transistor ST2 is connected to a source of the memory cell transistor MTn.

In the present embodiment, the (m+1) memory cell transistors MTi connected to the same word line WLi are referred to as memory cell group. In a case where the memory cell is a single level cell (SLC), one memory cell group corresponds to one page. In a case where the memory cell is a multi-level cell (MLC), one memory cell group corresponds to two pages (lower page and upper page). In a case where the memory cell is a triple level cell (TLC), one memory cell group corresponds to three pages (lower page, middle page, and upper page). Furthermore, each memory cell is connected to a word line and connected to a bit line as well. Each memory cell can be identified by using an address identifying a word line and an address identifying a bit line.

In the present specification, in a case where the memory cell is the SLC, the page corresponds to the memory cell group. In a case where the memory cell is the MLC, the page corresponds to one of the lower page and the upper page. In a case where the memory cell is the TLC, the page corresponds to one of the lower page, the middle page, and the upper page.

The host I/F unit 2 is a communication interface such as the SATA (Serial Advanced Technology Attachment) or the SAS (Serial Attached SCSI). The host I/F unit 2 connects the memory system 100 and the host 1. The host I/F unit 2 receives a command such as a read command or a write command from the host 1. As for a command, an address of data to be transferred by the command, a size of the data, and the data are added to the command. Upon receiving a command from the host 1, the host I/F unit 2 allocates a necessary buffer area on the data buffer 4, and notifies the memory controller 3 of the command.

The data buffer 4 temporarily stores data transferred between the memory system 100 and the host 1. As the data buffer 4, for example, SRAM (Static Random Access Memory) or DRAM (Dynamic Random Access Memory) is used.

The memory controller 3 generally controls the memory system 100. A function of the memory controller 3 is implemented by a processor which executes firmware stored in the NAND 10, various hardware circuits and the like. The memory controller 3 performs, for example, processing of reading and writing on the NAND 10 in accordance with a command notified of by the host I/F unit 2.

The ECC encoder 41 encodes user data buffered in the data buffer 4, and generates a code word including data and a redundant unit (parity). The ECC decoder 40 acquires a code word read from the NAND 10, from the memory I/F unit 20, and decodes the acquired code word. If the ECC decoder 40 fails in error correction at the time of decoding, the ECC decoder 40 notifies the read control unit 32 and the error correction control unit 60 of a read error.

The memory I/F unit 20 is a controller that directly controls the NAND 10 in accordance with a control protocol of the NAND 10. The memory I/F unit 20 writes a code word input from the ECC encoder 41, in accordance with control from the write control unit 33 or the like. The memory I/F unit 20 reads a code word from the NAND 10 in accordance with control from the read control unit 32 or the like, and transfers the code word to the ECC decoder 40.

The memory I/F unit 20 includes an operation parameter setting unit 21. Operation parameters which are set by the error correction control unit 60 are set in the operation parameter setting unit 21. The memory I/F unit 20 executes writing into the NAND 10 and reading from the NAND 10 in accordance with the operation parameters which are set in the operation parameter setting unit 21. The operation parameters include a read voltage, a program voltage, and the like.

The data management unit (data manager) 30 manages which position on the NAND 10 data is to be stored in. The data management unit 30 has an address translation table 31 which manages correspondence between a logical address given by the host 1 and a physical position on the NAND 10, and performs garbage collection depending upon a use situation of blocks on the NAND 10.

The block management unit 50 manages blocks on the NAND 10. In the memory system 100, a logical block which is a virtual block is used as a management unit of blocks. A logical block is formed by collecting physical blocks from a plurality of memory chips #0 to #n−1. The logical blocks are managed by using a logical block management table 51. Details of the logical blocks will be described in a second embodiment. The block management unit 50 manages the blocks. Management information includes information such as configuration information of logical blocks, the number of times of block erasing (hereafter referred to as erase count), and a utilization state. The configuration information of a logical block is identifier (physical block numbers) of a plurality of physical blocks included in the logical block. The erase count is the number of times of block erasing in a logical block unit. The utilization state is used for distinguishing whether the block is an active block or a free block. The active block is a logical block having valid data recorded therein. The free block is a logical block having no valid data recorded therein. By the way, in the block management unit 50, the function of managing logical blocks is not necessary in the memory system in the first embodiment, and is used in a memory system in a second embodiment.

The read control unit 32 performs read processing from the NAND 10 in accordance with a command notified of by the host I/F unit 2. The read control unit 32 performs read processing by acquiring a physical position on the NAND 10 corresponding to a logical address of read data from the data management unit 30 and notifying the memory I/F unit 20 of the acquired physical position. Data that is read is transferred to the host 1 via the ECC encoder 41, the data buffer 4, and the host I/F unit 2.

The write control unit 33 performs write processing on the NAND 10 in accordance with a command notified of by the host I/F unit 2. The write control unit 33 acquires position information of a block into which data should be written, from the block management unit 50. The write control unit 33 performs write processing by outputting the position information of the block acquired from the block management unit 50 and a code word which is output from the ECC encoder 41 to the memory I/F unit 20. The write control unit 33 registers mapping between the logical address of the written data and the physical position on the NAND 10 into the data management unit 30.

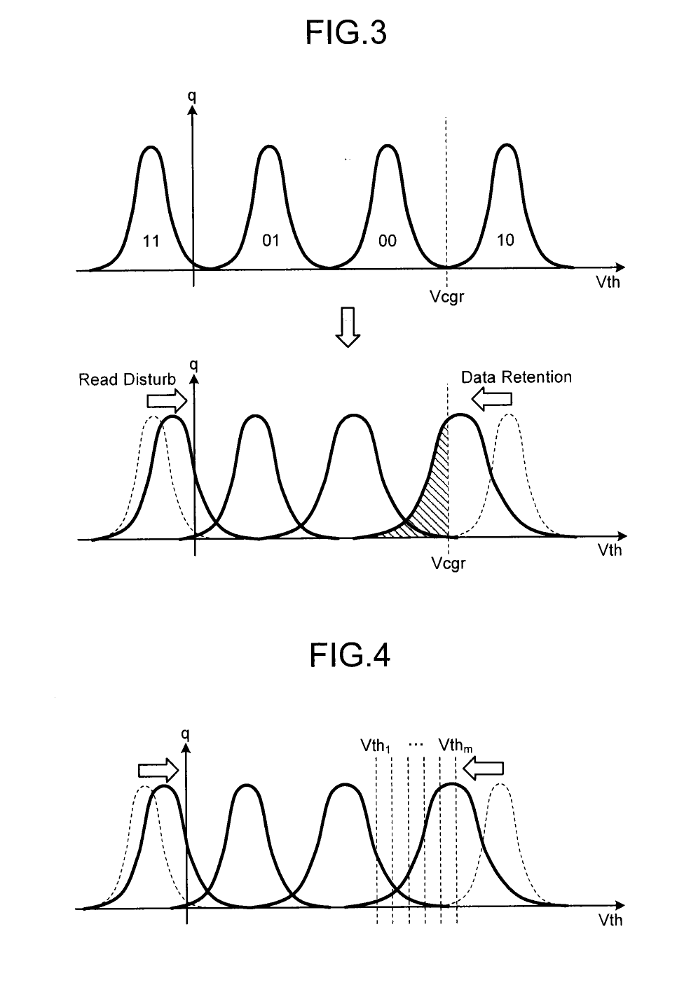

The error correction control unit 60 operates in a case where error correction fails and a read error occurs at the time of decoding in the ECC decoder 40. In the flash memory, data is recorded by programming a threshold voltage depending upon a value to be recorded in a memory cell. FIG. 3 illustrates an example of a change and distribution of a threshold voltage Vth in the NAND 10 of 2 bits/cell. An upper diagram in FIG. 3 illustrates distribution in an initial state. The ordinate axis indicates the number q of memory cells, and the abscissa axis indicates the threshold voltage. A first peak from the left indicates distribution corresponding to “11.” A second peak from the left indicates distribution corresponding to “01.” A second peak from the right indicates distribution corresponding to “00.” A first peak from the right indicates distribution corresponding to “10.” It can be identified whether each cell is programmed above a read voltage or below the read voltage by suitably setting the read voltage between peaks and conducting reading. FIG. 3 illustrates an example in which Vcgr is set as a read voltage used to identify cells programmed to “00” and “10” and reading is performed. By the way, the correspondence relation between “11” to “00” and the threshold voltage Vth is not restricted to that illustrated in FIG. 3, but other correspondence relations may also be used.

In the NAND 10 of 2 bits/cell illustrated in FIG. 3, the number of read voltages and the number of times of reading put to use differ depending upon whether the page is a lower page or an upper page. When reading a lower page, a read voltage is set between the peak “01” and the peak “00” and reading is performed. When reading an upper page, a read voltage is set between peaks differing in the upper bit, that is, in each of two places, i.e., a place between the peak “11” and the peak “01” and a place between the peak “00” and the peak “10” and reading is performed twice. In the upper page, therefore, two kinds of read voltage are used.

The threshold voltage of the flash memory changes due to influence of discharge caused by elapse of time and voltage application caused by reading in the block. A voltage drop due to influence of discharge caused by elapse of time is referred to as data retention. A voltage rise due to influence of voltage application caused by reading in the block is referred to as read disturb. Distribution of the threshold voltage changes because of such phenomena. A lower diagram in FIG. 3 illustrates a state in which distributions have changed. If the distributions change in this way, the threshold voltage of a cell in which “10” is originally recorded becomes lower than Vcgr or conversely the threshold voltage of a cell in which “00” is originally recorded becomes higher than Vcgr. As a result, the number of cells that cannot be identified correctly increases. A shaded portion in the lower diagram in FIG. 3 illustrates a cell that is identified falsely from “10” to “00.”

As a countermeasure against such an error, data to be recorded in the NAND 10 is encoded by the ECC encoder 41 and recorded. If the change of the threshold voltage becomes large and the number of errors at the time of decoding exceeds the capability of error correction, however, it becomes impossible to read correct data.

Therefore, there is a method of changing the read voltage (Vth1 to Vthm) little by little as illustrated in FIG. 4 when reading data in read target page, repeating data reading and error correction on the read target page, and searching for a suitable read voltage with which errors are held down to within the correction capability. In this method, however, reading of the read target page is repeated a plurality of times and consequently it takes a longer time to perform read processing. Furthermore, threshold voltage changes of the same tendency occur in pages in the block. Nevertheless, search processing of the read voltage is performed in a page unit. As a result, the number of times of reading in the block units increases. Consequently, there is a possibility that the influence of the read disturb will become further greater.

When searching for suitable operation parameters (including the read voltage) on a target page in which a read error has occurred, therefore, it is not conducted in the first embodiment to read the target page a plurality of times while changing the operation parameters. A plurality of physical blocks (referred to as test blocks as well) are selected, and one page is selected from each of the plurality of selected test blocks. And different operation parameters are set for each of a plurality of pages included in the plurality of selected test blocks, and reading is performed in parallel. Code words from the plurality of pages are decoded, and optimum operation parameters are selected on the basis of results of decoding of the code words.

Upon receiving a notice of a read error from the read control unit 32, the error correction control unit 60 selects a plurality of physical blocks besides a physical block Berr including an error page in which the read error has occurred, as test blocks. In other words, p (where p≧2) test blocks B(0) to B(p−1) are selected inclusive of the physical block Berr. The test blocks are selected out of physical blocks used equally with the physical block Berr. The physical blocks used equally are selected out of, for example, physical blocks that are close in the erase count to the physical block Berr, physical blocks programmed at time close to that of the physical block Berr, or physical blocks that are close in the number of times of being read to the physical block Berr. It is desirable that p test blocks are blocks that can be read in parallel.

The error correction control unit 60 selects operation parameters to be searched for. Here, the read voltage is adjusted as an operation parameter. A plurality of different read voltages V0 to Vs to be searched for are set for each search area in the error correction control unit 60. The search area in a case where the memory cell is an MLC is two areas in the upper page and one area in the lower page. The error correction control unit 60 assigns the plurality of read voltages V0 to Vs to p test blocks B(0) to B(p−1). By the way, in a case where the number s of candidates of read voltage to be searched for is greater than the number p of test blocks, different read voltages are set for the same test block and reading from the same test block is performed a plurality of times. Conversely, in a case where s is less than p, the number of test blocks can be set equal to s.

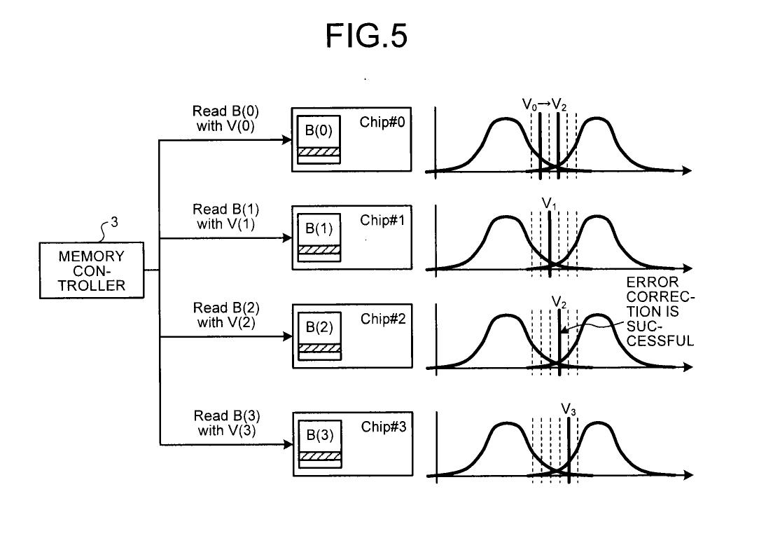

FIG. 5 is a diagram conceptually illustrating search for a read voltage according to the first embodiment. In the ensuing description, operation in a case where the memory cell is an SLC will be described for simplicity. In this case, it is supposed that a physical block B(0) in a chip #0 is the physical block Berr. As test blocks, a physical block B(1) in a chip #1, a physical block B(2) in a chip #2, and a physical block B(3) in a chip #3 are selected besides the physical block B(0) in the chip #0. The blocks B(0) to B(3) belong to different chips and parallel operation is possible. For pages in the block B(0), reading is performed with a read voltage V0. For pages in the block B(1), reading is performed with a read voltage V1. For pages in the block B(2), reading is performed with a read voltage V2. For pages in the block B(3), reading is performed with a read voltage V3.

Page data in the block B(0) read with the read voltage V0, page data in the block B(1) read with the read voltage V1, page data in the block B(2) read with the read voltage V2, and page data in the block B(3) read with the read voltage V3 are decoded by the ECC decoder 40, and it is determined whether error correction is successful. And a read voltage used to read a page for which error correction is determined to be successful is selected as an optimum read voltage. In FIG. 5, for example, in the page data in the block B(2) read by using the read voltage V2, error correction is successful. The read voltage V2 is selected as the optimum read voltage. Thereafter, therefore, re-reading using the optimum read voltage V2 is performed on the error page in the physical block Berr (the block B(0)).

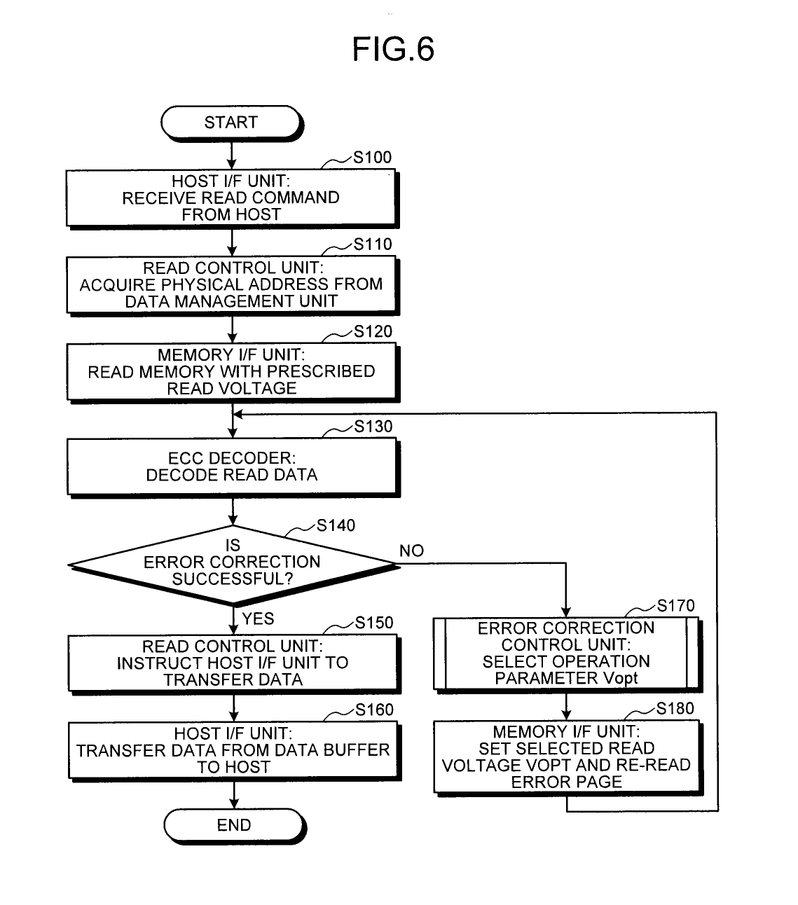

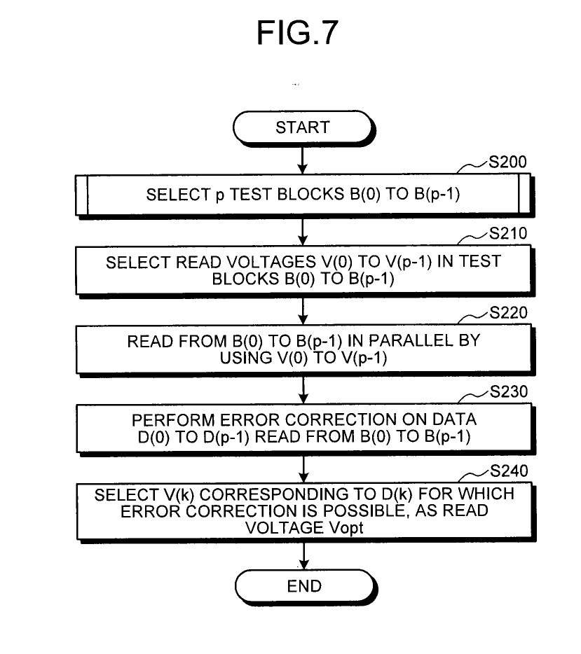

Hereafter, read processing in the first embodiment will be described with reference to flow charts illustrated in FIGS. 6 and 7. FIG. 6 generally illustrates read processing of the memory system 100. FIG. 7 illustrates selection processing of the optimum read voltage.

Upon receiving a read command from the host 1 (step S100), the host I/F unit 2 notifies the memory controller 3 of the read command. The read control unit 32 acquires a physical address corresponding to a logical address of read target data from the data management unit 30 (step S110). In accordance with an instruction from the read control unit 32, the memory I/F unit 20 reads data from a read target page in the NAND 10 with a read voltage having a preset prescribed value (step S120).

The memory I/F unit 20 inputs page data read from the NAND 10 to the ECC decoder 40. The ECC decoder 40 decodes the read data (step S130). In a case where error correction is successful (step S140: Yes), the ECC decoder 40 notifies the read control unit 32 that the error correction had been successful, and buffers the data into the data buffer 4. The read control unit 32 instructs the host I/F unit 2 to transfer the data (step S150). The host I/F unit 2 transfers the data from the data buffer 4 to the host 1 (step S160).

In a case where error correction is failed (step S140: No), the ECC decoder 40 notifies the read control unit 32 of a read error and suspends the read operation of the data once. The read control unit 32 notifies the error correction control unit 60 of occurrence of the read error and causes the error correction control unit 60 to perform selection processing of an optimum read voltage Vopt. The error correction control unit 60 performs selection processing of the optimum read voltage Vopt (step S170). The selection processing of the optimum read voltage Vopt will be described in detail later with reference to FIG. 7.

Upon completion of selection of the optimum read voltage Vopt, the memory I/F unit 20 sets the selected read voltage Vopt in the operation parameter setting unit 21 and re-reads the error page (step S180). Then, data in the error page re-read is decoded by the ECC decoder 40 (step S130). If the error correction succeeds (step S140: Yes), the decoded data is transferred to the host 1 via the data buffer 4 (steps S150 and S160).

The selection processing of the optimum read voltage Vopt will now be described with reference to FIG. 7. The error correction control unit 60 selects p (where p≧2) test blocks B(0) to B(p−1) inclusive the physical block Berr (step S200). As described earlier, the test blocks B(0) to B(p−1) are selected out of blocks estimated to be used equally with the physical block Berr. It is desirable that p test blocks are blocks capable of being read in parallel. The error correction control unit 60 specifies read target pages respectively in the test blocks B(0) to B(p−1). By the way, it is desirable that pages read respectively in the test blocks are pages having the same page number.

Then, the error correction control unit 60 selects candidates V(0) to V(p−1) of the read voltage to be searched for, and assigns one of the candidates to each of the pages respectively in the test blocks B(0) to B(p−1) (step S210). Furthermore, the error correction control unit 60 sets respective page addresses in the test blocks B(0) to B(p−1) and the candidates V(0) to V(p−1) of the read voltage into the operation parameter setting unit 21. The memory I/F 20 performs read operation on pages respectively in the test blocks B(0) to B(p−1) in the NAND 10 by using different read voltages V(0) to V(p−1) in accordance with contents set in the operation parameter setting unit 21 (step S220). For example, the memory I/F 20 sets V(k) as the read voltage and performs read operation from the block B(k). At this time, the memory I/F 20 starts setting of the next V(k+1) and read operation of B(k+1) without waiting for completion of the read operation of B(k). The memory I/F 20 executes read operation of B(0) to B(p−1) in parallel.

The memory I/F unit 20 inputs data of a plurality of pages (p pages) read from the plurality of test blocks B(0) to B(p−1), to the ECC decoder 40. The ECC decoder 40 decodes data in the plurality of pages and notifies the error correction control unit 60 of decoding results of respective pages via the read control unit 32. The error correction control unit 60 refers to decoding results of respective pages and determines whether error correction has succeeded in each page. And the error correction control unit 60 selects a read voltage used in a page in which error correction has succeeded, as the optimum read voltage Vopt. By the way, in a case where there are a plurality of page data in which error correction has succeeded, one read voltage is selected by using a suitable algorithm.

In this way, in the first embodiment, a plurality of test blocks are selected when searching for the optimum read voltage Vopt for a page in which a read error has occurred. And different read voltages are set for pages in the plurality of selected test blocks, and parallel reading is performed. Read data from the plurality of pages are decoded, and the optimum read voltage Vopt is selected on the basis of decoding results of the read data. As a result, operation time required when searching for the optimum read voltage Vopt can be shortened. Furthermore, influence of the read disturb can be distributed to a plurality of blocks.

### Second Embodiment

In a second embodiment, test blocks are selected out of physical blocks included in a logical block. As described earlier, it is desirable that
test blocks are used equally; and
test blocks are blocks which can be read in parallel.

Since it is preferable that changes in threshold voltage among the test blocks are approximately the same, it is desirable that the test blocks be used equally. Since the change of the threshold voltage is greatly influenced by exhaustion of the memory cell, blocks that are close in the erase count are desirable. Influence of the data retention depends on elapsed time since the block is programmed, and influence of the read disturb depends on the number of times of reading. As test blocks, therefore, blocks programmed at time points that are close and blocks storing data that are also close in the number of times of being read are desirable.

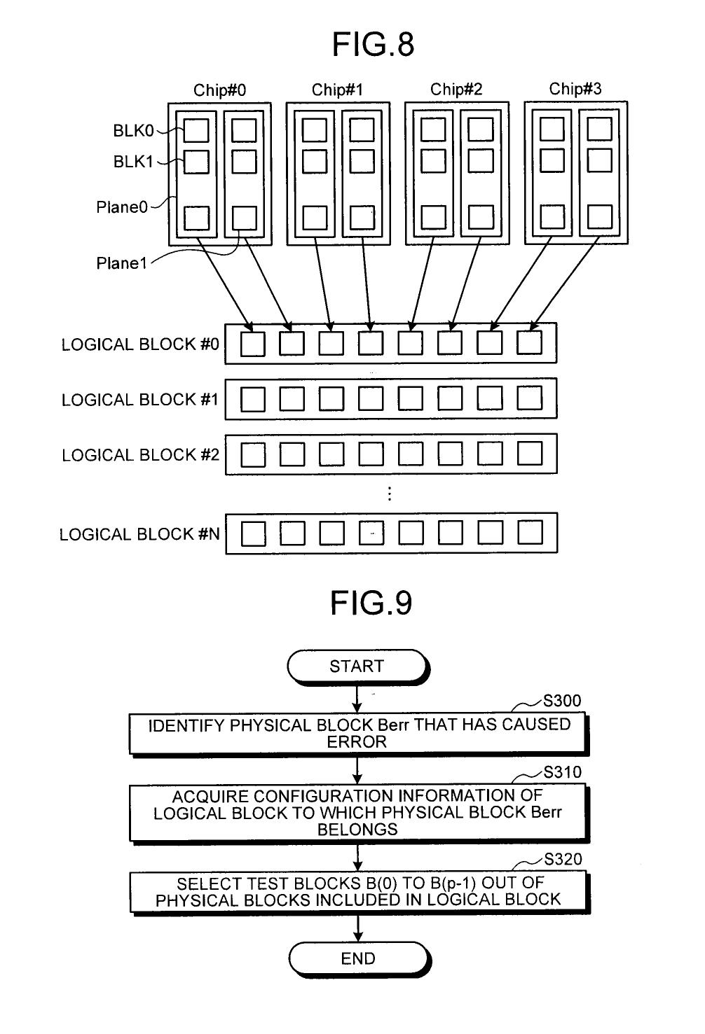

In the memory system 100, a logical block which is a virtual block is used as a management unit of blocks as described earlier. The logical block is formed by collecting physical blocks out of a plurality of memory chips #0 to #n. FIG. 8 illustrates a configuration example of logical blocks. In this example, the number of memory chips is set equal to four, and each of memory chips, chip #0 to chip #3, is divided into two districts, plane p0 and plane p1. Each of the plane p0 and the plane p1 includes a plurality of physical blocks BLK. The plane p0 and the plane p1 can be subjected to erasing/writing/reading at the same time. In the example illustrated in FIG. 8, logical blocks are formed by combining physical blocks such that chip parallelism and plane parallelism are performed. Since the number of memory chips is four and the number of planes is two in FIG. 8, each logical block includes eight physical blocks BLK.

A plurality of physical blocks included in a logical block are erased simultaneously and used as a logical block for writing. Therefore, a plurality of physical blocks included in a logical block become equal in the erase count. Furthermore, since data written from the host 1 at the same timing are recorded in the logical block, elapsed time since programming also becomes nearly the same. Furthermore, for example, in a case where data in one file is distributed to a plurality of physical blocks included in a logical block and recorded, it is considered that the physical blocks are also equal in the number of times of reading. Owing to the facts described heretofore, a plurality of blocks included in a logical block satisfy the condition of the test blocks.

The logical block is managed by the block management unit 50 as described earlier. The block management unit 50 includes the logical block management table 51 to manage logical blocks.

FIG. 9 illustrates a test block selection procedure in the second embodiment. Processing illustrated in FIG. 9 is performed at step S200 in FIG. 7. The error correction control unit 60 identifies a physical block Berr, on the basis of information supplied from the ECC decoder 40 via the read control unit 32 (step S300). The error correction control unit 60 acquires configuration information of a logical block to which the physical block Berr belongs (identification information of a plurality of physical blocks included in the logical block) from the block management unit 50 (step S310). The error correction control unit 60 selects test blocks B(0) to B(p−1) out of the plurality of acquired physical blocks.

In this way, the test blocks B(0) to B(p−1) are selected out of the plurality of physical blocks included in the logical block to which the physical block Berr belongs. Then, the read control unit 32 executes the processing at the step S170 in FIG. 6 by executing processing at steps S210 to S240 in FIG. 7, and the optimum read voltage Vopt is acquired.

In this way, in the second embodiment, test blocks are selected out of a plurality of physical blocks included in a logical block to which the physical block Berr including page data in which a read error has occurred belongs. As a result, physical blocks having similar tendencies in change of threshold voltage can be certainly selected as test blocks. In the second embodiment, the logical block is associated with the plurality of physical blocks to enable channel parallel operation and plane parallel operation. the logical block may be associated with the plurality of physical blocks to enable channel parallel operation, plane parallel operation, and bank interleaving operation. Bank interleaving allows a parallel operation by causing a plurality of memory chips connected to one common IO bus to execute an interleaving operation.

### Third Embodiment

In a third embodiment, the ECC decoder 40 and the ECC encoder 41 performs code processing of two kinds differing in error correction capability. First code processing is intra-page ECC. A redundant portion (parity) is created from data in the same page, and the created parity is recorded in the same page as the data. Second code processing is inter-page ECC. Parity is created from data distributed to a plurality of pages and stored. The created parity is recorded in a page different from the data.

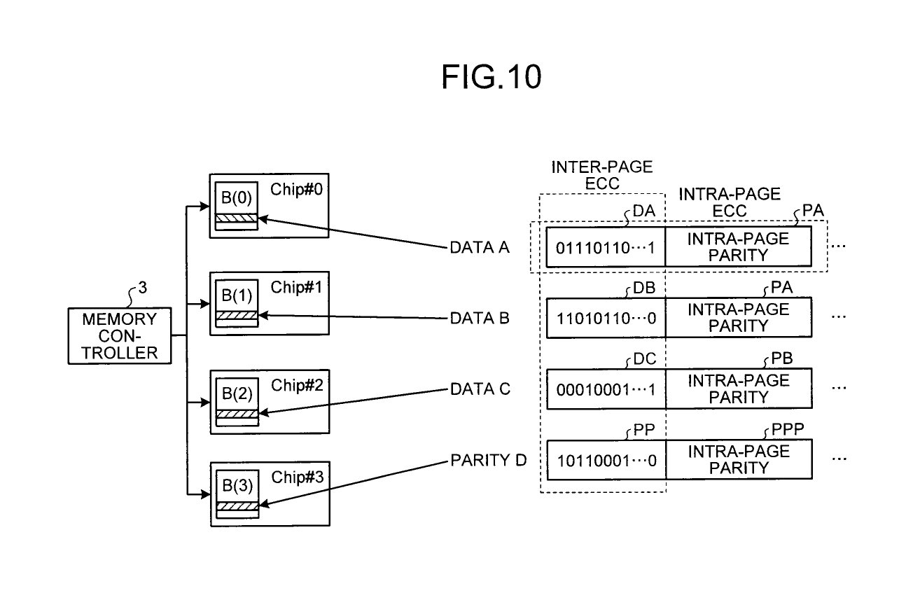

FIG. 10 conceptually illustrates the intra-page ECC processing and inter-page ECC processing. In FIG. 10, exclusive OR (XOR) is used as the inter-page ECC. In this example, an XOR operation is performed in a bit unit by using three data DA, DB and DC to generate an inter-page parity PP. Furthermore, the data DA is encoded with an intra-page ECC, and an intra-page parity PA which is a result of the encoding is recorded in the same page as the data DA. In the same way, intra-page parities PB, PC and PPP are created from the data DB and DC and the inter-page parity PP, and recorded in the same page as DB, DC and PP, respectively. A plurality of sets similar to a set of the data DA and the intra-page parity PA are included in page data A. The same is true of page data B, page data C, and parity D.

In the ECC decoder 40, decoding is performed by using the intra-page ECC when reading data. In a case where error correction has succeeded, decoded data is used as read data. In a case where error correction is failed, however, the ECC decoder 40 performs decoding by using the inter-page ECC.

Here, the page data. DA, DB and DC and the inter-page parity PP included in the inter-page ECC are distributed to a plurality of physical blocks B(0) to B(p−1) included in the same logical block and recorded.

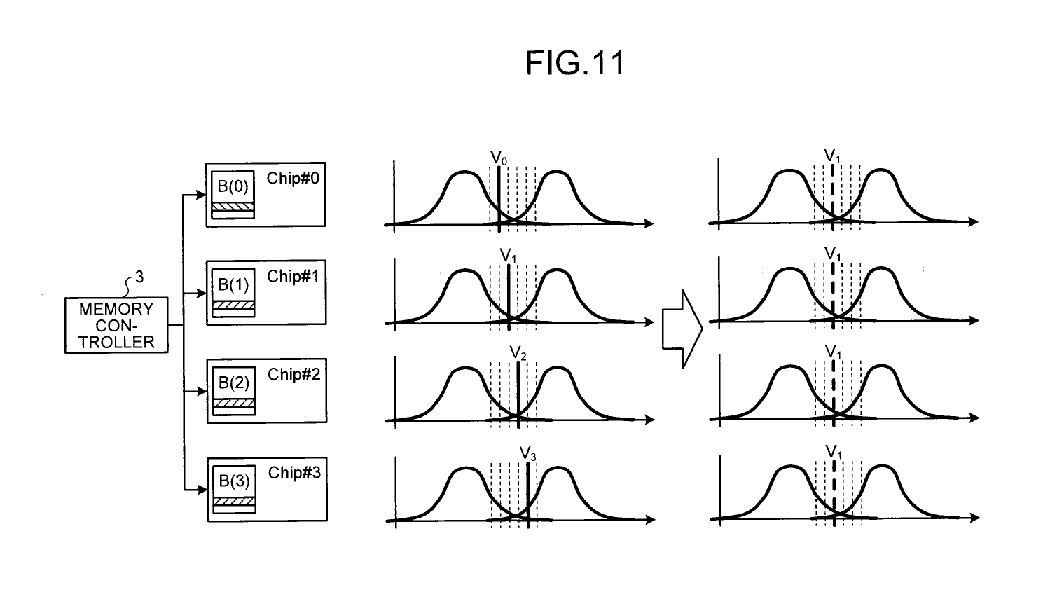

FIG. 11 is a diagram conceptually illustrating search for the read voltage and data re-reading in the third embodiment. In the third embodiment, in a case where a read error has occurred in decoding using an intra-page ECC, a logical block to which a physical block Berr belongs is identified and test blocks are selected out of a plurality of physical blocks included in the identified logical block. In FIG. 11, a block B(0) in a chip #0, a block B(1) in a chip #1, a block B(2) in a chip #2, and a block B(3) in a chip #3 are selected as the test blocks. It is supposed that the block B(0) is the block Berr. Then, data reading is performed by using read voltages V0 to V3 which differ from block to block. An optimum read voltage is selected on the basis of decoding results using the intra-page ECC. In FIG. 11, the read voltage V1 is selected as the optimum read voltage Vopt.

It is not true that if the optimum read voltage Vopt is determined, the optimum read voltage Vopt is set only in the block Berr and data in the block Berr is re-read. If the optimum read voltage Vopt is determined, the optimum read voltage Vopt is also set for pages in physical blocks including other data or parities included in the inter-page ECC. And page data are read from a plurality of physical blocks including a plurality of data and parities included in the inter-page ECC. And page data in the block Berr is restored by decoding a plurality of read page data with the inter-page ECC. In FIG. 11, the read voltage V1 selected as the optimum read voltage Vopt is used to read from a plurality of blocks included in the inter-page ECC.

By the way, when selecting test blocks, the physical block Berr may not be included in the test blocks. This is because a case where the cause of correction failure with an intra-page ECC is not increase of random errors caused by deviation of the threshold voltage, but a burst error caused by a failure of hardware is also considerable.

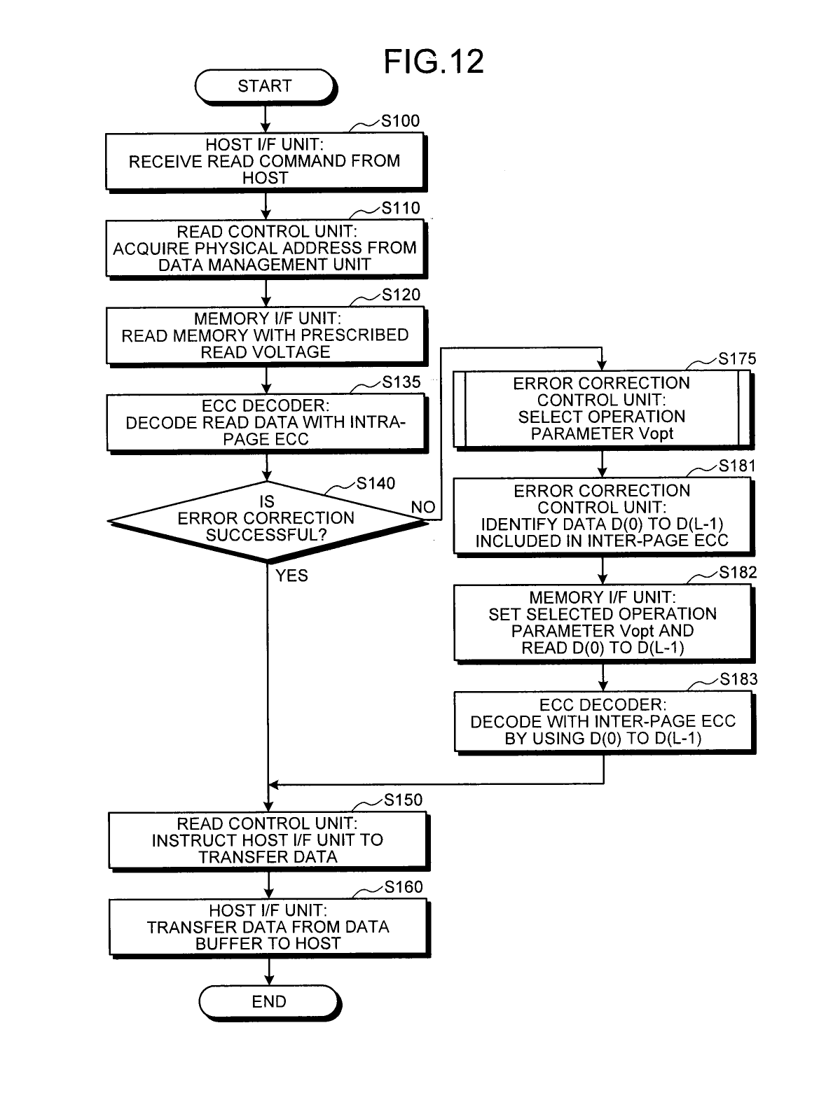

Hereafter, read processing in the third embodiment will be described with reference to a flow chart illustrated in FIG. 12. In FIG. 12, the step S130 in FIG. 6 is changed to step S135 and the step S180 in FIG. 6 is changed to steps S181 to S183. Duplicated description will be omitted.

The memory I/F unit 20 inputs page data read from the NAND 10 to the ECC decoder 40. The ECC decoder 40 decodes read data by using the intra-page ECC (step S135). In a case where error correction has succeeded (step S140: Yes), the ECC decoder 40 notifies the read control unit 32 that the error correction had been successful, and buffers data into the data buffer 4. The read control unit 32 instructs the host I/F unit 2 to transfer data (step S150). The host I/F unit 2 transfers data from the buffer 4 to the host 1 (step S160).

In a case where error correction is failed as a result of decoding using the intra-page ECC (step S140: No), the ECC decoder 40 notifies the read control unit 32 of an error and suspends the read operation of the data once. The read control unit 32 instructs the error correction control unit 60 to perform selection processing of the optimum read voltage Vopt. The error correction control unit 60 performs selection processing of the optimum read voltage Vopt (step S175).

At the step S175, the error correction control unit 60 executes processing of steps S300 to S320 illustrated in FIG. 9. In other words, the error correction control unit 60 acquires configuration information of the logical block to which the physical block Berr belongs to, from the block management unit 50. The error correction control unit 60 selects test blocks B(0) to B(p−1) out of a plurality of acquired physical blocks. Then, the error correction control unit 60 acquires the optimum read voltage Vopt by executing the processing of the steps S210 to S240 in FIG. 7.

Upon acquiring the optimum read voltage Vopt, the error correction control unit 60 identifies a code word in an inter-page ECC including page data in which the read error has occurred, by using management data in the block management unit 50 (step S181). In other words, symbols D(0) to D(L−1) included in the identified code word are identified. L is the number of symbols included in the code word in the inter-page ECC. The symbols include data, which is an information symbol, and parity, which is a redundant symbol.

The memory I/F unit 20 sets the optimum read voltage Vopt on each of pages including the symbols D(0) to D(L−1) and reads the symbols D(0) to D(L−1) from each page (step S182). The memory I/F unit 20 inputs the symbols D(0) to D(L−1), which are read, to the ECC decoder 40. The ECC decoder 40 performs decoding with the inter-page ECC by using the symbols D(0) to D(L−1), which are read, and restores page data in which the read error has occurred (step S183). The ECC decoder 40 notifies the read control unit 32 that page data in which the read error has occurred had been restored, and buffers the restored page data into the data buffer 4. The read control unit 32 instructs the host I/F unit 2 to transfer the data. The host I/F unit 2 transfers the data from the buffer 4 to the host 1 (step S160).

According to the third embodiment, when restoring page data that has caused a read error with the inter-page ECC, the optimum read voltage Vopt is set for all pages included in the inter-page ECC and re-reading is performed, in this way. As a result, the probability of success of error correction using the inter-page ECC can be increased.

### Fourth Embodiment

At the step S120 in FIG. 6, for the first time, data is read from the NAND 10 by using a read voltage of a prescribed value. In the block management unit 50 in a fourth embodiment, the optimum read voltage Vopt with which reading has succeeded is recorded in a block unit. At the time of reading for the first time in the fourth embodiment, a read voltage of a prescribed value is not used, but read operation is performed by using the read voltage Vopt of the last time recorded in the block management unit 50.

By the way, in the first to third embodiments, data is read from a second block other than a first block including a page in which a read error has occurred, optimum operation parameters for the second block are determined on the basis of a result of error correction on the read data, and the determined operation parameters are used as operation parameters for the first block. In the first to third embodiments, therefore, a concept that operation parameters are diverted among physical blocks is included. In the present invention, therefore, an embodiment in which error correction is performed on page data read from a first physical block, operation parameters suitable for the first physical block are selected on the basis of a result of the error correction, and the selected operation parameters are applied to read processing of a second physical is also possible.

While certain embodiments have been described herein, these embodiments have been presented by way of example only, and are not intended to limit the scope of the present invention. Indeed, the novel embodiments described herein may be embodied in a variety of other embodiments; furthermore, various omissions, substitutions and changes in the form of the embodiments described herein may be made without departing from the spirit of the invention. The accompanying claims and their equivalents are intended to cover such embodiments or modifications as would fall within the scope and spirit of the invention.

What is claimed is:

1. A method of controlling a nonvolatile memory including a plurality of blocks, each of the blocks being a unit of data erasing, each of the blocks including a plurality of pages, each of the pages being a unit of data writing and reading, the method comprising:
reading a plurality of first pages in parallel based on respectively different operation parameters, each of the first pages being respectively included in a plurality of first blocks, each of the operation parameters including a read voltage, and
performing error correction on each of read data, and selecting one operation parameter out of the plurality of different operation parameters based on a result of the error correction.

2. The method according to claim 1, the method further comprising erasing the plurality of first blocks in parallel.

3. The method according to claim 2, wherein the selected operation parameter is an operation parameter that has been applied to a page in which the error correction has succeeded among the plurality of first pages.

4. The method according to claim 3, the method comprising:
erasing a plurality of second blocks in parallel; and
reading second pages included in the plurality of second blocks in parallel based on the selected operation parameter.

5. The method according to claim 4, the method comprising:
managing number of times of block erasing based on a logical block associated with a plurality of blocks capable of operating in parallel.

6. The method according to claim 5, the method comprising:
selecting the plurality of second blocks as an application target of the selected operation parameter based on the number of times of block erasing.

7. The method according to claim 3, the method comprising:
in a case where there is a page in which the error correction has failed, re-reading the plurality of first pages in parallel based on the selected operation parameter.

8. The method according to claim 2, the method comprising:
in response to a read request of a page included in the plurality of first pages, reading the plurality of first pages based on a predetermined read voltage; and
in a case where error correction for data of the reading has failed, executing parallel reading based on the respectively different operation parameters and selection of the operation parameter.

9. The method according to claim 3, the method comprising in response to a read request of a page included in the plurality of first pages, reading the plurality of first pages in parallel based on the selected operation parameter.

10. The method according to claim 3, wherein
the plurality of first pages include a page in which parity generated from data in a plurality of third pages is stored, the plurality of third pages being among the plurality of first pages, and
the method comprising, in a case where there is a page in which the error correction has failed, re-reading the plurality of first pages in parallel on the basis of the selected operation parameter and performing decoding by using an inter-page ECC.

11. The method according to claim 1, wherein the nonvolatile memory is a NAND type flash memory.

12. A method of controlling a nonvolatile memory including a plurality of physical blocks, each of the physical blocks including a plurality of pages, the control method comprising:
selecting one page out of each of the plurality of first physical blocks, setting respectively different operation parameters for the plurality of selected pages, and reading data from the plurality of pages in parallel, the operation parameters including a read voltage;
performing error correction on the read data of the plurality of pages and selecting one operation parameter out of the plurality of operation parameters based on a result of the error correction; and
performing reading on a page within a second physical block by using the selected one operation parameter.

13. The method according to claim 12, wherein the second physical block includes a page in which a read error has occurred.

14. The method according to claim 12, further comprising managing logical blocks, a plurality of physical blocks capable of operating in parallel belonging to each of the logical blocks,
wherein
the second physical block is a block including a page in which a read error has occurred, and
the plurality of first physical blocks are selected out of a plurality of physical blocks belonging to a first logical block, the second physical block belonging to the first logical block.

15. The method according to claim 12, the method comprising
creating first parity from a plurality of data stored in a plurality of different pages, and forming a first code word, the first code word including the plurality of data and the first parity;
in a case where a read error has occurred, acquiring a first code word including data in which the read error has occurred, and selecting a plurality of third blocks which are the plurality of first physical blocks respectively including the plurality of data and the first parity forming the first code word;
selecting one page out of each of the plurality of third physical blocks, setting respectively different operation parameters for the plurality of selected pages, and reading data from the plurality of pages in parallel;
performing error correction on the plurality of read pages, and selecting one operation parameter out of the plurality of operation parameters based on a result of the error correction; and
reading the plurality of data and the first parity included in the first code word by using the selected one operation parameter.

16. The method according to claim 15, further comprising managing logical blocks, a plurality of physical blocks capable of operating in parallel belonging to each of the logical blocks,
wherein the first code word includes data in a plurality of physical blocks belonging to a logical block.

17. The method according to claim 15, further comprising:
creating second parity from data in same page and forming a second code word by using the data in the same page and the second parity; and
in a case where the read error has occurred in error correction on the second code word, acquiring the first code word including page data in which the read error has occurred.

18. The method according to claim 12, further comprising
recording the selected operation parameter in a physical block unit, and executing next reading by using the selected operation parameter.

19. A method of controlling nonvolatile memory including a plurality of physical blocks, each of the physical blocks including a plurality of pages, the method comprising:
performing error correction on page data read from a first physical block, and selecting operation parameters for the first physical block based on a result of the error correction, the operation parameters including a read voltage; and
applying the selected operation parameters to read processing of the second physical block.

20. The method according to claim 19, wherein the operation parameters for the first physical block are selected in a case where the error correction has succeeded.
